(19) United States
(12) Patent Application Publication
(10) Pub. No.: US 2013/0260155 A1
(43) Pub. Date: Oct. 3, 2013

(54) RESIN COMPOSITION, AND PREPREG AND LAMINATE USING SAME

(71) Applicants: Tetsuro Niiyama, Kashima-shi (JP); Yoshihisa Sone, Kashima-shi (JP)

(72) Inventors: Tetsuro Niiyama, Kashima-shi (JP); Yoshihisa Sone, Kashima-shi (JP)

(73) Assignee: AIR WATER INC, HOKKAIDO (JP)

(21) Appl. No.: 13/824,899

(22) PCT Filed: Oct. 19, 2011
(86) PCT No.: PCT/JP2011/074598

§ 371 Date: Jun. 20, 2013

(30) Foreign Application Priority Data
Oct. 29, 2010 (JP) 2010-243048

(51) Int. Cl. C09D 179/08; H05K 1/03; H05K 1/05

(52) U.S. Cl. CPC C09D 179/08; H05K 1/056; H05K 1/0353
USPC 428/413; 428/418; 524/538

(57) ABSTRACT

A resin composition having high Tg (high heat resistance), low thermal expansion, and excellent flame retardancy, and being advantageous for promoting halogen-free, and having excellent adhesiveness with Cu, a prepreg obtained by impregnating it into substrate, and a composite and a laminate obtained from them. Specifically provided are a modified polyimide resin composition containing (A) a polymaleimide compound of formula [1], (B) epoxy resin having at least two glycidyl groups in the molecule of formula [2], and (c) phenolic compound having at least two OH groups in the molecule, and a prepreg obtained by impregnating the composition into the substrate, and a composite and a laminate obtained from the prepreg.

### TECHNICAL FIELD

This invention relates to a resin composition and a prepreg using it, as well as a composite material and a laminate obtained from it, which are used in the field of electronic and electrical parts and in the field of electronic material such as printed wiring board, semiconductor substrate and IC encapsulant, and which are in particular, exhibit excellent flame retardancy without including halogen-containing flame retardant or phosphorus-containing flame retardant, and are suitable for a printed wiring board and a semiconductor substrate where high temperature resistance and flame retardancy are required.

### BACKGROUND ART

The flame retardancy is required to secure safety for fire in the electronic material field. As thereof, For the laminate material used for printed wiring board and semiconductor substrate, there is UL-94 standard by Underwriters Laboratories Inc. as a representative standard for the flame retardancy, and it is required that the laminate material preferably passes V-1 test condition in case of vertical flame test, and more preferably passes V-0 test condition. Until now, the resin used in such field includes the halogen-containing compound such as bromine-containing compound as flame retardant, in order to pass this condition. Although these halogen containing compounds have excellent flame retardancy, however, such halogen containing compounds, for example aromatic bromine containing compounds, have not only a possibility to generate bromine or hydrogen bromide having corrosiveness due to thermal decomposition, but also a possibility to form a highly toxic compound in the presence of oxygen (refer to non-patent literature 1).

For this reason, the material not including a halogen compound, that is, “halogen free” material has been developed (for example, refer to non-patent literature 1, or the like). Among them, as a flame retardant alternative to a halogen-containing compound, the phosphorus-containing compounds such as a red phosphorus, has mainly been investigated. However, a phosphorus-containing flame retardant has a risk to generate a toxic phosphorus compound such as a phosphine when burning, and further, when a typical phosphoric acid ester is used as a phosphorus-containing compound flame retardant, there is a drawback that moisture resistance of a composition is significantly damaged.

On the other hand, a metallic hydroxide is known as an another flame retardant, for example, it is known that an aluminum hydroxide is effective as a flame retardant resulted from the following reaction releasing a crystal water during heating.

2Al(OH)₃→Al₂O₃+3H₂O

However, in case of using metallic hydroxide such as aluminum hydroxide alone as a flame retardant, a large amount of addition is needed to obtain the required flame retardancy. In case of the laminate, in which a common epoxy resin is used and an aluminum hydroxide is added as a flame retardant, the addition amount of aluminum hydroxide needed for achieving V-0 level of UL-94 standard is about 70 wt % to 75 wt % based on resin composition, and even in case of using the resin having a skeleton hard to burn, addition of about 50 wt % of aluminum hydroxide is needed (refer to non-patent literature 2). In case of a large amount of aluminum hydroxide addition, properties of the resin composition and the laminate formed by the resin, for particular example, moisture resistance and heat resistance after absorbing moisture (solder dip resistance), are significantly reduced (refer to non-patent literature 2). Since the moisture resistance and the heat resistance after absorbing moisture effect greatly to the reliability on packaging when the laminate is used as semiconductor substrate, improvement of the properties is required.

When evaluating the flame retardancy of the laminate, conventionally, the evaluation is frequently carried out by using a thick specimen of 1.6 mm. However, according to the trend for compactization of electronic equipment, thickness of the laminate using as semiconductor substrate is required to be less than 0.5 mm, preferably less than 0.2 mm. When the thickness of the laminate becomes thinner, the laminate more easily contacts with oxygen during burning and more easily burns, and thus generally, a large amount of flame retardant is required. Therefore, in order to obtain the laminate having satisfactory flame retardancy as the thin laminate, sufficient moisture resistance, and solder dip resistance after absorbing moisture, the resin composition having further higher flame retardancy is required.

Recently, in the resin composition for these laminates, high heat treatment at the temperature of 260° C. or more has become necessary in the semiconductor packaging method by lead-free solder or the like, and thereby problem about warpage of package has become remarkable. In addition, high modulus at high temperature is also required accompanied with transition into Cu-wire bonding. In other word, to endure high temperature treatment, the material having high heat resistance (high Tg) and low thermal expansion is required.

Generally, it is considered that the material having high Tg becomes low warpage due to low thermal expansion, and can endure the treatment of Cu-wire bonding due to high modulus at high temperature. However, contrary to that this high Tg material has high heat resistance, there are drawbacks that this material is brittle, combustible and has poor adhesiveness. It is considered that the reason for poor adhesiveness is based on brittleness due to the use of high cross-linked epoxy resin (in case of flexible epoxy resin, Tg is low although the adhesiveness is good).

Until now, it is reported that by compositing the resin composition having a specific maleimide group and an epoxy resin (naphthol skeleton-containing epoxy curing agent and/or epoxy resin), the resin composition having high Tg and low thermal expansion can be obtained (refer to non-patent literature 3, 4). However, in order to give flame retardancy, a halogenated flame retardant such as brominated epoxy resin is needed to be used (refer to patent literature 5), or a large amount of metallic hydroxide such as aluminum hydroxide is needed to be used. However, even in this case, it was difficult to obtain the sufficient flame retardancy which can endure the severe flame retardant test to be carried out in 0.2 mm or less of thin plate. Meanwhile, in case of using specific epoxy resin having a naphthalene ring for improving heat resistance under the moisture absorption condition required in the substrate material, it is known that sufficient heat resistance can be obtained (refer to patent literature 6). However, because the heat resistance and the flame retardancy do not always coincide, it was difficult to obtain resin composition having both of sufficient heat resistance and flame retardancy.

Although the compatibility of high Tg and flame retardancy is an important issue, both properties go against in the conventional thermo-setting resin, and thus there has not existed the material sufficiently satisfying these needs. Therefore, appearance of such material has been desired.

### CITATION LIST

### Patent Literature

PATENT LITERATURE 1: JP-A-2003-231762;
PATENT LITERATURE 2: JP-A-2001-226465;
PATENT LITERATURE 3: JP-A-2003-119348;
PATENT LITERATURE 4: JP-A-2003-147170;
PATENT LITERATURE 5: JP-A-2004-307673;
PATENT LITERATURE 6: JP-A-2003-335925;

### Non-Patent Literature

NON-PATENT LITERATURE 1: Journal of The Japan Institute of Electronics Packaging 5(2), pp. 159˜165 (2002);
NON-PATENT LITERATURE 2: Flame proofing of polymer, TAISEISHA Ltd., pp. 69˜79 (1992), “Halogen type flame retardant”;

### SUMMARY OF INVENTION

### Problem to be Solved by the Invention

It is an object of the present invention to provide a resin composition having high Tg (high heat resistance), low thermal expansion, and excellent flame retardancy.

The present invention is to provide the resin composition which is advantageous for halogen-free because of high Tg and excellent flame retardancy, and which is also excellent in adhesive property with Cu.

### Means for Solving the Problem

The present invention is to provide a modified polyimide resin composition which contains

(A) the polymaleimide compound represented by the following general formula [1];

(B) the epoxy resin having at least two glycidyl groups in the molecule represented by the following general formula [2]; and

(C) the phenolic compound having at least two OH groups in the molecule;

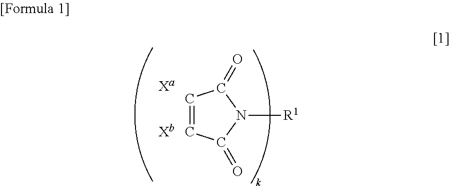

(wherein, R¹ represents a k valence organic group, X^{a}, X^{b} may be the same or different, and represents one valence atom or group selected from a hydrogen atom and an organic group, k represents an integer of 2 or more.)

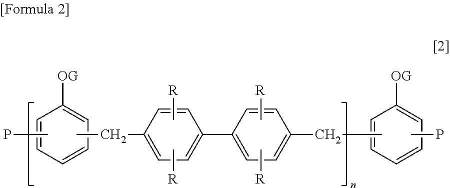

(wherein, n represent an average value, and represents 1 to 15 value, G represents a glycidyl group, R may be the same or different, and represents a hydrogen atom, an alkyl group or an alkene group having 1 to 8 carbon numbers, P represents a hydrogen atom, an alkyl group, an alkene group or aromatic hydrocarbon group.).

The modified polyimide resin obtained by reacting the above-mentioned resin composition by heat treatment, in particular, the modified polyimide resin obtained by reacting at least between (A) and (C), is the preferable embodiment of the present invention.

The present invention also provides the modified polyimide resin composition containing the compound selected from the group consisting of the above-mentioned (A), (B) and (C), and further (D) glycidyl ether compound and (E) the compound having at least one active hydrogen.

The present invention further provides the prepreg obtained by impregnating in the above-mentioned modified polyimide resin composition substrate; the composite obtained by heating and pressing the one which is laminated with one piece or a plurality of pieces of said prepreg; and the laminate obtained by integrating a metallic foil on one surface or both surfaces of the most outer layer of the one laminated with one piece or a plurality of pieces of said prepreg.

### Effect of the Invention

According to the present invention, the resin composition which has high Tg (high heat resistance), low thermal expansion, and excellent flame retardancy is provided. Since the resin composition of the present invention has high flame retardancy, it can obtain the sufficient flame retardancy even the laminate becomes thin such 0.5 mm or less of thickness. In addition, because of the high flame retardancy of the resin composition, it becomes possible that addition of the flame retardant such as a metallic hydroxide or the like, which may degrade the hygroscopic property, is unnecessary or that addition amount of the flame retardant make smaller compared with the conventional case. Consequently, the resin composition and the laminate formed by it is the one having high moisture resistance and heat resistance under hygroscopic condition.

The resin composition of the present invention has the excellent property such that the resin composition exhibits high Tg maintaining high flame retardancy, and has high adhesive strength with Cu without using a high cross-liked epoxy resin.

### BRIEF DESCRIPTION OF THE DRAWINGS

FIG. 1 is a chart of molecular weight measurement by FD-MS method of the modified polyimide resin composition obtained from Example 1.

### DESCRIPTION OF THE INVENTION

The present invention provides the modified polyimide resin composition which contains:

(A) the polymaleimide compound represented by the following general formula[1];

(B) the epoxy resin having at least two glycidyl groups in the molecule represented by the following general formula[2]; and

(c) phenolic compound having at least two OH group in the molecule.

The polyimide resin composition (herein below, called simply as the resin composition) pertaining to the present invention is explained below in more detail.

### The Resin Composition

The polymaleimide compound (A) to be used in the present invention is the compound which has two or more maleimide groups in one molecule represented by the following general formula[2]:

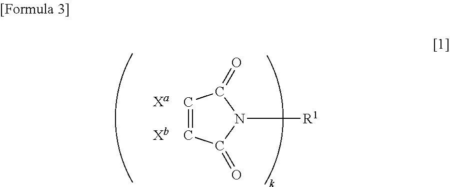

wherein, R¹ represents a k valence organic group, X^{a}, X^{b} may be the same or different one valence atom or group selected from a hydrogen atom and an organic group, and k represents an integer of 2 or more, preferably 2 to 10.

Preferable polymaleimide compound can include the compound in which R¹ in the general formula[1] is the one selected from the group consisting of the following general formula[3].

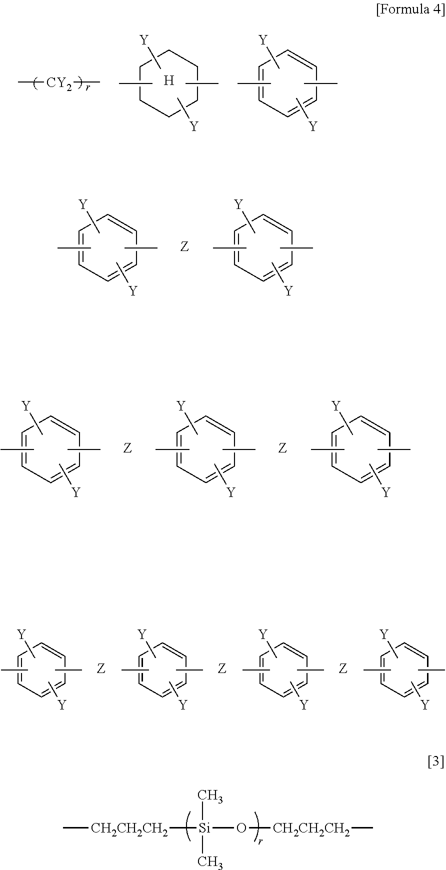

Wherein, z represents —CY₂—, —CO—, —O—, —S—, —SO₂—, Y represents —CH₃, CH₃ CH₂—, CH₃O—, —OH, —NH₂ o r a hydrogen atom, and may be the same or different. Also, r represents an integer of 1 to 10.

In the general formula [1], as an organic group, an alkyl group having 1 to 20 carbon number such as a methyl group can be exemplified.

Such a polymaleimide compound can include, for example,
N,N′-ethylenebismaleimide,
N,N′-hexamethylenebismaleimide,
N,N′-(1,3-phenylene)bismaleimide,
N,N′-[1,3-(2-methylphenylene)]bismaleimide,
N,N′-(1,4-phenylene)bismaleimide,
bis(4-maleimidephenyl)methane,
bis(3-methyl4-maleimidephenyl)methane,
bis(4-maleimidephenyl)ether,
bis(4-maleimidephenyl)sulfone,
bis(4-maleimidephenyl)sulfide,
bis(4-maleimidephenyl)ketone,
bis(4-maleimidecyclohexyl)methane,
1,4-bis(4-maleimidephenyl)cyclohexane,
1,4-bis(4-maleimidemethyl)cyclohexane,
1,4-bis(maleimidemethyl)benzene,
1,3-bis(3-maleimidephenoxy)benzene,
bis[4-(4-maleimidephenoxy)phenyl]methane,
1,1-bis[4-(3-maleimidephenoxy)phenyl]ethane,
1,1-bis[4-(4-maleimidephenoxy)phenyl]ethane,
1,2-bis[4-(3-maleimidephenoxy)phenyl]ethane,
1,2-bis[4-(4-maleimidephenoxy)phenyl]ethane,
2,2-bis[4-(4-maleimidephenoxy)phenyl]propane,
2,2-bis[4-(3-maleimidephenoxy)phenyl]butane,
2,2-bis[4-(4-maleimidephenoxy)phenyl]butane,
4,4′-bis(3-maleimidephenoxy)biphenyl,
4,4′-bis(4-maleimidephenoxy)biphenyl,
bis[4-(3-maleimidephenoxy)phenyl]ketone,
bis[4-(4-maleimidephenoxy)phenyl]ketone,
bis[4-(3-maleimidephenoxy)phenyl]sulfide,
bis[4-(4-maleimidephenoxy)phenyl]sulfide,
bis[4-(3-maleimidephenoxy)phenyl]sulfoxide,
bis[4-(4-maleimidephenoxy)phenyl]sulfoxide,
bis[4-(3-maleimidephenoxy)phenyl]sulfone,
bis[4-(4-maleimidephenoxy)phenyl]sulfone,
bis[4-(3-maleimidephenoxy)phenyl]ether,
bis[4-(4-maleimidephenoxy)phenyl]ether,
1,4-bis[4-(4-maleimidephenoxy)-α,α-dimethylbenzyl]benzene,
1,3-bis[4-(4-maleimidephenoxy)-α,α-dimethylbenzyl]benzene,
1,4-bis[4-(3-maleimidephenoxy)-α,α-dimethylbenzyl]benzene,
1,3-bis[4-(3-maleimidephenoxy)-α,α-dimethylbenzyl]benzene,
1,4-bis[4-(4-maleimidephenoxy)-3,5-dimethyl-α,α-dimethylbenzyl]benzene,
1,3-bis[4-(4-maleimidephenoxy)-3,5-dimethyl-α,α-dimethylbenzyl]benzene,
1,4-bis[4-(3-maleimidephenoxy)-3,5-dimethyl-α,α-dimethylbenzyl]benzene,
1,3-bis[4-(3-maleimidephenoxy)-3,5-dimethyl-α,α-dimethylbenzyl]benzene, or the like. In addition, a polymaleimide compound represented by the following general formula[4], and a polymaleimide compound represented by the general formula [5], and a polymaleimide compound represented by the general formula[6] or the like can be included as preferable example. In addition, these polyimide compounds may be used alone or in combination of two or more kinds

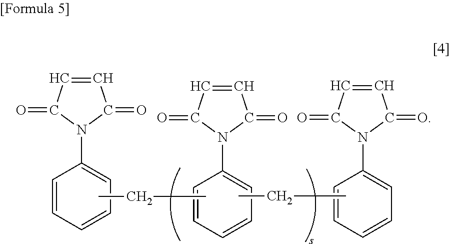

(wherein, s is average data, and 0 to 10.)

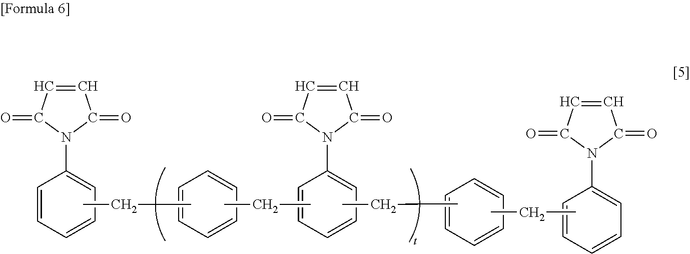

(wherein, t is average data, and 0 to 10)

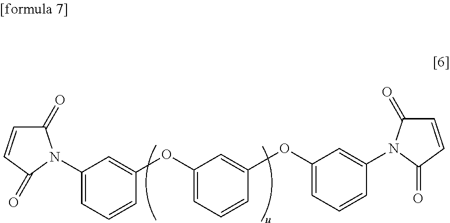

(wherein, u is average data, and 0 to 6)

Epoxy resin (B) to be used in the present invention is the epoxy resin having at least two glycidyl groups in the molecule represented by the following general formula[2].

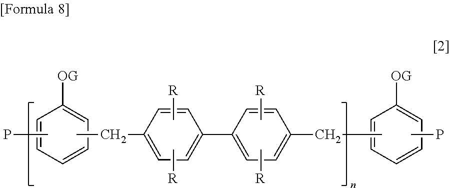

Wherein, n represents average data, and takes the value of 1 to 15. G represents a glycidyl group, R represents any one of a hydrogen atom, an alkyl group or an alkenyl group having 1 to 8 carbon numbers, and respective R may be the same or different each other. An alkyl group includes a methyl group, a butyl group, a 2-ethylhexyl group, a decyl group, a stearyl group or the like, an alkene group includes an allyl group or the like, and an aromatic hydrocarbon group includes a phenyl group, a sec-butylphenyl group or the like. P represents a hydrogen atom or an alkyl group, an alkene group, an aromatic hydrocarbon group. R and P are preferably a hydrogen atom.

The epoxy resin (B) of the present invention can be used by selecting appropriately from the commercially available products. For example, the product, in which P═H, R═H in the above-described general formula[2], is available from the product NC-3000 produced by NIPPON KAYAKU Co., Ltd.

The phenolic compound (C) having at least two OH groups in the molecule to be used in the present invention can include the phenolic compound represented by the following general formula [7].

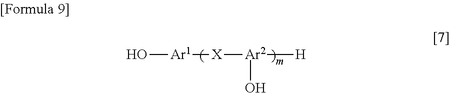

(wherein, Ar¹, Ar² is a phenylene group represented by the following general formula [8] or a naphthalene group represented by the following general formula [9], respectively.

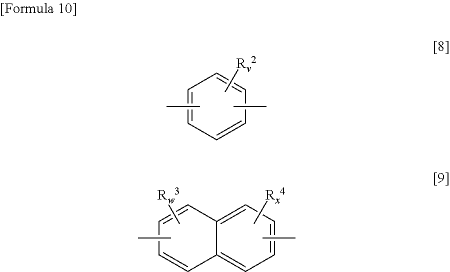

in the above formula, X represents any one of a direct bond, an alkylene having 1 to 4 carbon numbers, an alkylene having 8 to 15 carbon numbers including an aromatic ring, O, S, or SO₂; as an alkylene, a methylene or the like can be represented, as an alkylene having 8 to 15 carbon numbers including an aromatic ring, the one having the structure of phenylene, naphthalene, biphenylene or the like can be represented. R², R³ and R⁴ are a hydrocarbon group or a hydroxyl group respectively, and v, w, and x are integers of 0 to 3 respectively, m is an integer of 0 or more, provided that m is 0, Ar ¹ is the one having at least one hydroxyl group.)

Specific example of phenolic compound (C) of the present invention can include hydroquinone, resorcin, catechol, pyrogallol, phloroglucin; biphenols such as o,m′-biphenol, o,p′-biphenol, m,m′-biphenol, m,p′-biphenol, p,p′-biphenol; bisphenols such as bisphenol F, bisphenol A; 1,2-dihydroxynaphthalene, 1,3-dihydroxynaphthalene, 1,4-dihydroxynaphthalene, 1,5-dihydroxynaphthalene, 1,6-dihydroxynaphthalene, 1,7-dihydroxynaphthalene, 1,8-dihydroxynaphthalene, 2,3-dihydroxynaphthalene, 2,6-dihydroxynaphthalene, 2,7-dihydroxynaphthalene, and furthermore, the known phenolic resin type curing agent such as phenol novolac resin, cresol novolac resin, phenol aralkyl resin, phenol naphthyl alkyl resin, triphenol methane type novolac resin, dicyclopentadiene type phenolic resin, naphthol aralkyl resin, biphenyl aralkyl resin or the like. Among them, biphenyl aralkyl resin and phenol aralkyl resin are preferable, and naphthol aralkyl resin is more preferable.

Glycidyl ether compound (D) which may be included in the modified polyimide resin composition of the present invention can include the glycidyl ether compound represented by the following general formula[10].

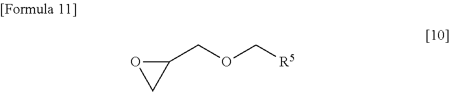

Wherein, R⁵ represents one valence group selected from an alkyl group, an alkene group and an aromatic hydrocarbon group. As an alkyl group, an alkyl group having 1 to 20 carbon numbers is preferable, and a methyl group, a butyl group, a 2-ethylhexyl group, a decyl group, a stearyl group or the like is included, and as an alkene group, the alkene group having 2 to 20 carbon numbers is preferable, and an ally group or the like is included, and as an aromatic hydrocarbon group, an aromatic hydrocarbon group having 6 to 20 carbon numbers is preferable, a phenyl group, a sec-butylphenyl group or the like is included.

By containing these glycidyl ether compounds, resin becomes easily solubilized in the solvent when varnishing reaction is carried out by using the common solvent such as acetone, methyl ethyl ketone, therefore, the uniform solution-like varnish suitable for prepreg making can be obtained. Further, when resin curing reaction is carried out, the resin cured material is incorporated into the resin skeleton by ring opening reaction of a glycidyl group, therefore, the resin cured material does not cause the reduction of mechanical strength and chemical resistance.

In addition, in order to achieve the high moisture resistance that is the important property in the electronic material use, R² having no hydrophilic group is preferable, further in order to improve dielectric property, the group selected from an alkyl group, an alkene group, an aromatic hydrocarbon group is preferable. Specific example of these glycidyl compounds include alkyl glycidyl ether such as methyl glycidyl ether, butyl glycidyl ether, 2-ethylhexyl glycidyl ether, decyl glycidyl ether, stearyl glycidyl ether; alkene glycidyl ether such as allyl glycidylether; and aromatic glycidyl ether such as phenyl glycidyl ether, sec-butylphenyl glycidyl ether, and the like.

As the compounds (E) which may have at least one active hydrogen, which may further be included in the modified polyimide resin composition of the present invention, the compound which would have at least one active hydrogen in the molecule can be fully used. Preferable example of the compounds having at least one active hydrogen in the molecule include phenols such as phenol, bisphenol A, bisphenol F, cresol, resorcinol, naphthol, dihydroxynaphthol; amines such as aniline, aminophenol, phenylene diamine, ethylene diamine, bis(4-aminophenyl)methane; the compounds having one alcoholic or phenolic OH group, and one or more epoxy groups such as glycidol, glycerin diglycidyl ether, ethylene glycol monoglycidyl ether, resorcinol monoglycidyl ether, naphthoresorcinol monoglycidyl ether; the compounds having OH group and acetylene group such as propargyl alcohol or the like.

Resin composition of the modified polyimide resin composition of the present invention is described as below.

Based on 100 parts by mass of polymaleimide compound of (A) component, total blending amount of epoxy resin of (B) component and the phenolic compound of (C) component is 10 to 500 parts by mass, preferably 25 to 300 parts by mass, and the ratio of numbers of OH groups in the phenolic compound of (C) component to numbers of glycidyl groups in the epoxy resin of (B) component is the range of 0.2 to 5.0, preferably the range of 0.5 to 3.0. In addition, blending amount of glycidyl ether compound of (D) component is 3 to 100 parts by mass, preferably 5 to 50 parts by mass, further preferably 7 to 20 parts by mass.

When the total blending amount of the epoxy resin of (B) component and the phenolic compound of (C) component is in the above-described range, excellent adhesive strength with metallic foil and metallic plate can be obtained. When numbers of OH groups in the phenolic compound of (C) component to numbers of glycidyl groups in the epoxy resin of (B) component is in the above-described range, excellent curing of the resin composition can be obtained. In addition, blending amount of glycidyl compound of (D) component is preferably in the above-described range, from the standpoints of uniformity of slurry when producing the modified resin varnish, uniformity of film thickness when producing the prepreg, and appearance problem such as pin hole.

It is preferable for the resin composition of the present invention to further include a curing accelerator. Example of the curing accelerators includes imidazoles such as 2-methylimidazole, 2-ethyl-4-methylimidazole, 2-heptadecylimidazole, 2-ethyl-4-methylimidazole tetraphenylborate; amines such as triethanolamine, triethylenediamine, N-methylmorpholine; tetraphenylboronic salts such as triethylammonium tetraphenylborate; 1,8-diaza-bicyclo[5.4.0]undecene-7 and derivatives thereof, or the like. These curing accelerators may be used alone, or in the combination of two or more kinds.

Content of these curing accelerators is preferably compounded so that the desired gelation time of varnish or prepreg, which is described later, can be obtained, however, generally, it is used in the range of 0.005 to 5 parts by mass relative to 100 parts by mass of total amount of the resin component (total amount of (A)+(B)+(C)+(D)+(E) components)

An inorganic filler may be added in the resin composition of the present invention. Preferable example of kind of the inorganic filler includes silica, alumina, titanium oxide, talc, calcined talc, kaolin, mica, clay, aluminum nitride, glass, aluminum hydroxide, oxyaluminum oxide or the like. Silica, alumina, titanium oxide, talc, aluminum hydroxide, and oxyaluminum oxide are more preferable, silica, talc, and oxyaluminum oxide are particularly preferable. Hardness of silica, alumina, and titanium oxide is so high that they are possible to contribute to improve the modulus by small amount addition. As for the shape, in the case when spherical filler is used, when the varnish (herein below, it may be called simply as “resin varnish”) of the resin composition is formed, it does not cause viscosity to increase extremely, workability thereafter becomes excellent, thus it is preferable. As a silica, a spherical silica is a preferable inorganic filler. As for a talc, when it is, in particular, the flattened shape, it is possible to contribute to improve the flexural modulus. Content of the inorganic filler, generally, is preferably used in the range of 0 to 200 parts by mass relative to 100 parts by mass of the total amount (total amount of (A)+(B)+(C)+(D)+(E) components) of the resin component.

The other additives can be added into the resin composition of the present invention dependent on its use.

Preferable example of the other additive includes the additive which is generally used as anti-foaming agent, leveling agent, and surface tension adjuster. Specific example includes anti-foaming agent such as fluorine type, silicone type, acryl type, and leveling agent. Content of the other additive is generally preferably used in the range of 0.0005 to 5 parts by mass relative to 100 parts by mass of the total amount of resin component (total amount of (A)+(B)+(C)+(D)+(E) components).

In addition, the flame retardant may be added into the resin composition of the present invention, if necessary. When the flame retardant is used, the well-known one appropriately selected from the organic flame retardant and the inorganic flame retardant can be used.

Adjusting method of the resin composition

The composition of the present invention is obtained as follows:

(A) the at least two or more valence maleimide compound represented by the above-described general formula[1];

(B) the epoxy resin having at lest two or more glycidyl groups in the molecule of the above-described general formula[2]; and

(C) the phenolic compound having two or more OH groups in the molecule;

are mixed, and further, if necessary,

(D) glycidyl ether compound and/or (E) the compound having at least one active hydrogen are added, and are mixed with the necessary additive components under heating to form the resin composition. Condition of mixing under heating is preferably at a temperature of 80 to 200° C., for 1 to 10 hours. Also, these components are mixed under heating in the organic solvent to produce the resin composition, and at the same time the resin varnish can be produced. When mixing under heating is carried out in the organic solvent, depending on the boiling temperature of organic solvent, about 0.1 to 30 hours is generally needed at 50 to 200° C.

The resin varnish is the one obtained by dissolving the resin composition into the solvent. That is, the resin varnish is obtained in such a way that the resin composition obtained from that (D) and/or (E) component are mixed under heating with the above-described (A), (B) and (C) component as needed, is dissolved in the solvent. In addition, as above-described, the resin varnish can be produced at the same time of producing the resin composition by mixing under heating the these components in the organic solvent.

As a solvent to be used for obtaining the resin varnish, ethylene glycol monoethyl ether, propylene glycol monomethyl ether, ethylene glycol monobutyl ether, N,N-dimethylformamide, N,N-dimethylacetamide, dioxane, acetone, N-methyl-2-pyrrolidone, dimethylsulfoxide, methyl ethyl ketone, methyl isobutyl ketone, cyclohexanone, 2-heptanone or the like can be used, however, the solvent having comparatively low boiling temperature is preferable, and thus methyl ethyl ketone, acetone, dioxane, or a mixture composing of these solvents as main component are preferably used.

It is preferable that in the resin varnish, 40 to 80% by mass, preferably 50 to 70% by mass of the above-described resin component is included. In addition, in the resin varnish, the above-described inorganic filler can be added.

The modified polyimide resin composition (a) obtained by the Examples to be described later, is thought as the adduct between BMI-S of the polyimide compound to be described later and SN-485 of the naphthol aralkyl resin to be described later, and the compound (F) having a maleimide group and a phenolic OH group in the same molecule, which is represented by the following general formula[F-1] to [F-4].

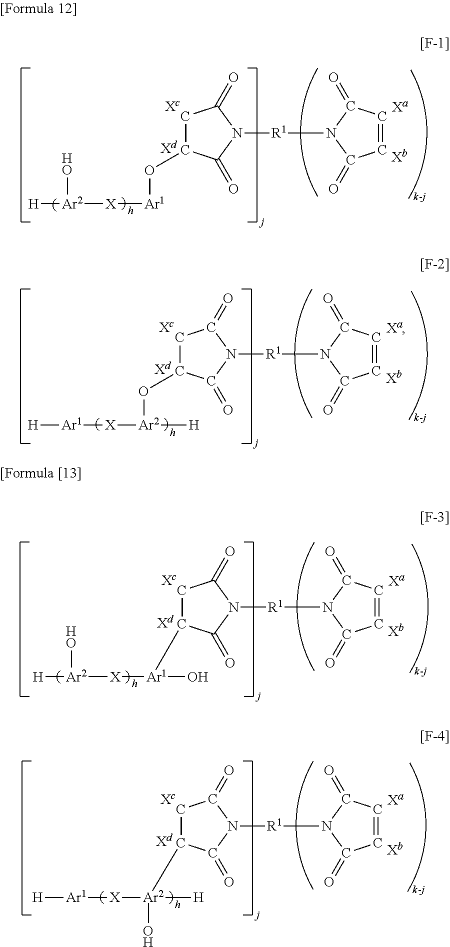

Wherein, R¹ is the k valence organic group, X^{a}, X^{b}, X^{c}, and X^{d} are one valence atom or group selected from a hydrogen atom and the organic group which may be the same or different, k is an integer of 2 or more, and h, j are integers of 1 or more, and is k≧j.

Generally, polymaleimide compound is incompatible with epoxy resin, therefore, when resin varnish is produced, the resin is partly deposited, and layer separation between polymaleimide cured body and epoxy cured body is generated, and reduction of thermal resistance is caused, therefore, it was difficult to satisfy the properties of various substrate materials, however, these problems was solved by the modified polyimide resin composition of the present invention, and it is estimated that transformation to the above-described compound by addition reaction of the maleimide compound and the curing agent contributes to solve these problems. It is estimated that, there is a possibility this compound is a key material bonding the polymaleimide compound and the epoxy cured body by organic bonding, and due to this addition reaction, the compatibility of resins each other can be improved, therefore, it became to be possible to express the performance that satisfies the substrate property such as the flame retardancy or adhesive property possessed in epoxy resin while maintaining the high heat resistance possessed in maleimide.

### Prepreg

The prepreg of the present invention can be produced by the way that the above-described resin varnish is forced to be painted or impregnated into the substrate, then, solvent is removed by drying.

As a substrate, all of the well-known substrates conventionally used in prepreg, such as glass nonwoven fabric, glass cloth, carbon fiber cloth, organic fiber cloth, and paper can be used. After the above-described resin varnish is painted or impregnated into the above-described substrate, prepreg is produced via drying process, the conventional well-known method of painting method, impregnating method and drying method can be used, but especially it is not limited. Drying condition is appropriately determined due to the boiling point of the used solvent, however, too high temperature is not preferable, in addition, amount of residual solvent in the prepreg preferably becomes less than 3% by mass.

### Composite

The composite of the present invention can be obtained by a method that one piece of prepreg is thermally-cured by hot-pressing or the prepreg laminated with a plurality of pieces is thermally-cured by hot-pressing, and is integrated. The condition of hot-pressing when producing the composite is not particularly limited, heating temperature is 100 to 300° C., preferably 150 to 250° C., pressure is 10 to 100 Kg/cm², time for hot-pressing is about 10 to 300 min.

### Laminate

The laminate of the present invention is the plate produced by laminating and integrating with metallic foil or metallic plate on one surface or both surfaces of the composite. This laminate can be produced by the way that prepreg is thermally-cured and also is integrated with metallic foil or metallic plate based on that metallic foil or metallic plate is laminated and hot-pressed on one surface or both surfaces of one piece of prepreg, or metallic foil or metallic plate is laminated and hot-pressed on one surface or both surfaces of the the most exterior layer of prepreg laminated with a plurality of pieces. As metallic foil or metallic plate, copper, aluminum, iron, stainless steel or the like can be used. It is preferred that thermal curing condition is similar to that of producing the composite. In addition, the laminate for multi-layered printed wiring board may be produced by using inner core material.

### EXAMPLES

The present invention is specifically described by using Examples and Comparative Examples below, but it is not especially limited by these examples. Test methods of performance in the Example and Comparative Example are as follows.

(1) Glass transition temperature: Dynamic viscoelastic method;

(2) Flame retardancy: Measured in accordance with the test method of fire resistance in UL-Standard.

It should be noted that evaluation of flame retardancy is carried out by using copper-clad laminate having 0.2 to 0.3 mm thickness which is prepared by overlapping two pieces of prepreg;

(3) Peeling test of copper foil: Measured in accordance with JIS C-6481;

(4) Soldering heat resistance: In accordance with JIS C-6481, after water absorbing treatment of specimen for 3 hours under condition at 120° C., in 100% RH, it is floated in soldering bath at 300° C., for 120 second, then, whether bulge of copper foil part of the laminate is occurred or not is checked.

(5) Measurement of gelation time: About 0.5 cc of varnish is dropped on the hot plate adjusted at 170±1° C. in advance, and simultaneously timing by using stopwatch is started. In addition, immediately, sample is mixed in the range of 20 mm diameter on the hot plate by means of stick of fluorine resin sharpened at the tip, and is vertically lifted up about 30 mm from the hot plate every several seconds. When the sample is lifted up and then is dropped on the hot plate, viscous behavior of the sample is observed by visual inspection, and measured the required time until gelatin occurs. Measurement is carried out three times, its average time is determined as gelation time, and is round off to one decimal place.

(6) Measurement of viscosity: Measured in accordance with JIS C2103 5.3 and JIS K7117.

Temperature is adjusted in constant temperature water tank, when temperature reaches 25±1° C., measurement is carried out by means of apparatus of Brookfield type viscometer.

(7) Measurement of non-volatile component:

Measured in accordance with JIS C2103 5.4.

In aluminum cup measured its weight (W₀), about 2.0 g of varnish is weighed (W₁), and after maintained for 30 min. in oven adjusted at 200±3° C., it is taken from oven, and is cooled to room temperature in desiccator. Total weight of cooled sample and aluminum cup is weighed (W₂). Then, content of non-volatile component is calculated by the following expression, and is round off to two decimal places.

content of non-volatile component(%)={(W₂−W₀)/W₂}×100

Detail of the raw material used in Example and Comparative Example are as follows:

(1) Polymaleimide compound (A): BMI-S (trade name; content of nitrogen atom: about 8%; produced by Mitsui Chemicals Inc.).

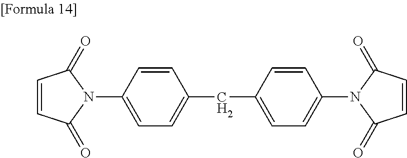 [SMILES: O=C1C=CC(=O)N1c1ccc(Cc2ccc(N3C(=O)C=CC3=O)cc2)cc1]

(2) Epoxy resin (B): Biphenyl aralkyl epoxy resin, NC3000H (trade name; epoxy equivalent: 290; produced by Nippon Kayaku Co., Ltd.)

(3) Phenolic resin: Naphthol aralkyl resin, SN485 (trade name; OH equivalent: 215; produced by Nippon Steel & Sumikin Chemical Co., Ltd.)

(4) Inorganic filler:

1): Aluminum hydroxide: average diameter of particle: 1.1 μm;

2) Oxyaluminum oxide: average diameter of particle: 2 μm;

3) Calcined talc: average diameter of particle: 3 μm;

4) Silica: average diameter of particle: 0.5, 1.5 μm;

(5) Curing accelerator; 2-ethyl-4-methylimidazole tetraphenylborate;

(6) Reactive diluent: allyl glycidyl ether;

### Example 1

In round bottom flask equipped with stirrer, thermometer and condenser tube, 270.0 g of bis (4-maleimidephenyl)methane, 82.0 g of naphthol aralkyl resin[SN-485, produced by Nippon Steel & Sumikin Chemical Co., Ltd], 221.0 g of biphenyl aralkyl epoxy resin [NC-3000-H, produced by Nippon Kayaku Co., Ltd.], 120.0 g of methyl ethyl ketone (MEK) were charged, after inner temperature reached 80° C., mixture was stirred for two hours. Then, 27.0 g of reactive diluent (allyl glycidyl ether), 12.0 g of N-methyl-2-pyrrolidone (NMP) were added, and the mixture was maintained at 80° C. for 18 hours.

Next, 28.0 g of (NMP) was added, and the mixture was further maintained at 80° C. for 18 hours. 200.0 g of MEK and 40.0 g of NMP were added, and stirred for two hours to obtain the varnish of the modified polyimide resin composition (I) having uniformly dissolved state.

Gelation time of the obtained varnish was 200 seconds at 170° C., viscosity was 120 mPa/s, and solid content of the resin was 62% by weight.

According to FD-MS analysis of the obtained varnish (I), as the modified polyimide resin composition (a) included in this resin varnish (I), component having 748 of molecular weight was detected. This component was the compound (F) which was the adduct of BMI-S and SN-485, and had a maleimide group and a phenolic OH group in the same molecule represented by the following formula[11] or formula[12].

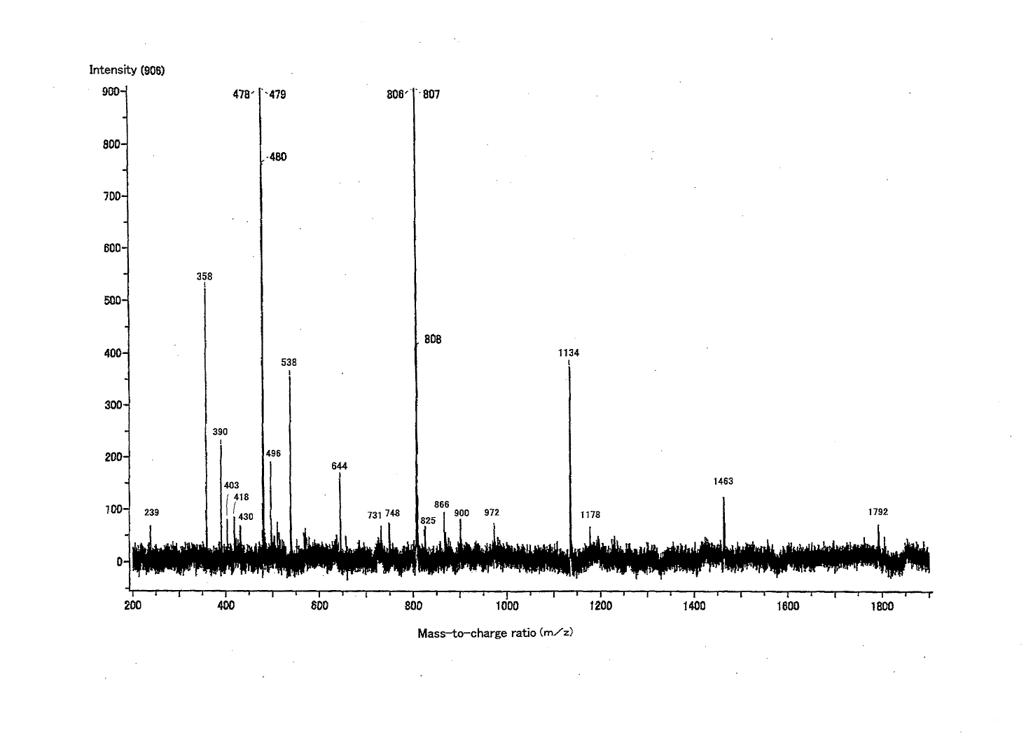

The measuring chart of the molecular weight by FD-MS method of the modified polyimide resin composition (a) included in this resin varnish was shown in FIG. 1.

[11] is the compound of k=2, j=1, and h=1, in the above-described general formula [F-1] and [F-2] and, [12] shows the same compound as the compound of k=2, j=1, and h=1 in the general formula [F-3] and [F-4].

In addition, large peak other than 748 of molecular weight in FIG. 1 is the peak derived from raw material. Peaks of 479, 807, 1134, 1463, and 1792 of molecular weight were the peak derived from NC3000-H of the raw material, also 358 of molecular weight was the peak derived from polymaleimide compound BMI-S of the raw material.

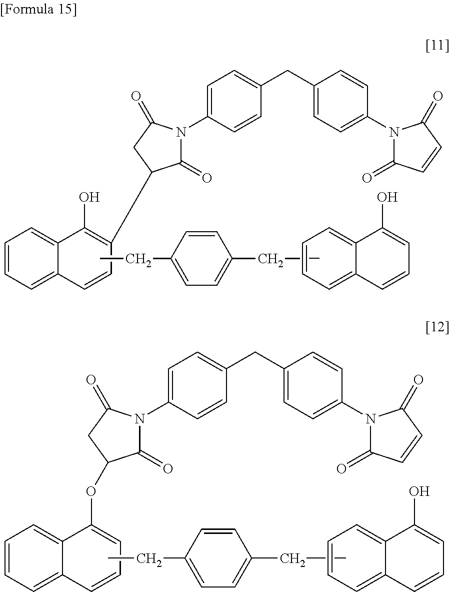

### Example 2

Into the varnish (I) of the modified polyimide resin composition obtained in Example 1, curing accelerator, additive (leveling agent), and inorganic filler (aluminum hydroxide) were added, and stirred homogeneously, and resin varnish was prepared. This was impregnated in glass cloth having 108 g/m² (about 100 μm thickness), was dried at 160° C., for 6 min., thus the prepreg having about 200 g/m² (about 100 μm thickness) was obtained. Two pieces of this prepreg were overlapped, further, 18 μm of copper foil was arranged at the most exterior layer of up and down thereof, and was formed by pressure of 2 MPa under heating condition at 180 to 230° C. for 120 min., thus the copper-clad laminate having 0.2 to 0.3 mm of thickness was obtained. Test results of the laminate obtained by this method were similarly shown in Table-1.

Composition of the modified polyimide curing resin composition of the obtained laminate was 25% by weight of resin, 17% by weight of aluminum hydroxide, 58% by weight of glass cloth.

Test results of the laminate obtained by this method were similarly shown in Table-1. Tg (glass transition temperature), flame retardancy, peeling strength, and solder dip resistance were all excellent.

### Example 3

The laminate was prepared by the similar method as Example 2 except omitting the use of aluminum hydroxide, and increasing the weight ratio of glass cloth/resin in Example 2. Composition of the modified polyimide curing resin composition of the obtained laminate was 29% by weight of resin and 71% by weight of glass cloth. Test results of the obtained laminate were shown in Table-1.

Tg (glass transition temperature), flame retardancy, peeling strength, and solder dip resistance were all excellent. Flame retardancy was high even without adding aluminum hydroxide.

### Example 4

The laminate was prepared by the similar method as Example 2 except using calcined talc instead of aluminum hydroxide in Example 2.

Composition of the modified polyimide curing resin composition of the obtained laminate was 30% by weight of resin, 15% by weight of calcined talc, 55% by weight of glass cloth. Test results of the obtained laminate were shown in Table-1.

Tg (glass transition temperature), flame retardancy, peeling strength, and solder dip resistance were all excellent.

### Example 5

The laminate was prepared by the similar method as Example 2 except using oxyaluminum oxide instead of aluminum hydroxide in Example 2. Composition of the modified polyimide curing resin composition of the obtained laminate was 25% by weight of resin, 17% by weight of oxy aluminum oxide, 58% by weight of glass cloth. Test results of the obtained laminate were shown in Table-1.

Tg (glass transition temperature), flame retardancy, peeling strength, solder dip resistance were all excellent.

### Example 6

The laminate was prepared by the similar method as Example 2 except using silica instead of aluminum hydroxide in Example 2.

Composition of the modified polyimide curing resin composition of the obtained laminate was 25% by weight of resin, 7.25% by weight of silica having average diameter of particle 0.5 μm, 17.75% by weight of silica having average diameter of particle 1.5 μm, 50% by weight of glass cloth. Test results of the obtained laminate were shown in Table-1.

Tg (glass transition temperature), flame retardancy, peeling strength, solder dip resistance were all excellent.

### Comparative Example 1

In Example 1, the following EXA-4710 (produced by DIC Corp: 2,7-DON type epoxy oligomer: epoxy equivalent 173) was used instead of biphenyl aralkyl epoxy resin, and in composition ratio of Table-1, the varnish (II) of the modified polyimide resin composition was obtained by the similar operation as Example 1.

The obtained varnish (II) was heterogeneous.

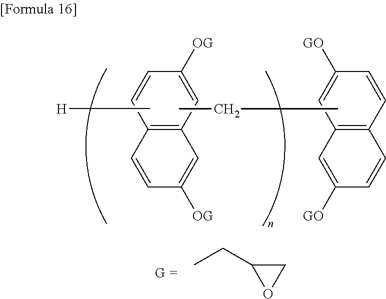

Wherein, n=1 to 6.

### Comparative Example 2

In Example 1, the following JER1032 (produced by Mitsubishi Chemical Corp; triphenol methane type epoxy resin: epoxy equivalent 170) was used instead of biphenyl aralkyl epoxy resin, and in composition ratio of Table-1, the varnish (III) of the modified polyimide resin composition was obtained by the similar operation as Example 1.

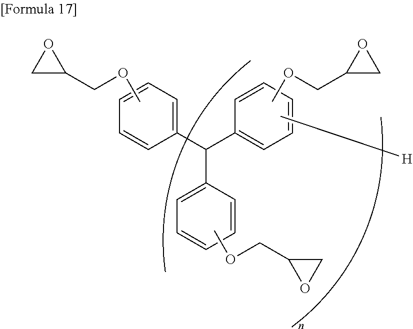

Wherein, n=1 to 5.

### Comparative Example 3

In Example 1, the following JER1001 (produced by Mitsubishi Chemical Corp; bisphenol A type epoxy resin: epoxy equivalent 475) was used instead of biphenyl aralkyl epoxy resin, and in composition ratio of Table-1, the varnish (IV) of the modified polyimide resin composition was obtained by the similar operation as Example 1.

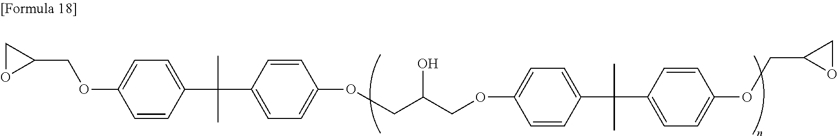

Wherein, n=1 to 5.

### Comparative Example 4

By using the varnish (II) obtained in Comparative Example 1, the laminate was tried to obtain, however, the varnish cannot be used due to heterogeneity, and prepreg cannot be formed.

### Comparative Example 5

By using the varnish (III) of the modified polyimide resin composition obtained in Comparative Example 2, the prepreg and the copper-clad laminate were obtained by the similar operation (condition) as Example 2 in the composition ratio described in Table-1. Evaluation results of this characteristics was described in Table-1 as well.

In test of flame retardancy of this laminate, test specimen was completely burned down.

### Comparative Example 6

By using the varnish (IV) of the modified polyimide resin composition obtained in Comparative Example 3, the prepreg and the copper-clad laminate were obtained by the similar operation (condition) as Example 2 in the composition ratio described in Table-1. Evaluation results of this characteristics was described in Table-1 as well.

In test of flame retardancy of this laminate, test specimen was completely burned down.

### Comparative Example 7

By using the varnish (IV) of the modified polyimide resin composition obtained in Comparative Example 3, prepreg and copper-clad laminate was obtained by the similar operation (condition) as Example 2 in the composition ratio described in Table-1. Evaluation results of this characteristics was described in Table-1 as well. Different point from Comparative Example 6 is to have changed the impregnation rate of glass cloth, and to have reduced the resin impregnation rate from 30% to 46%.

In test of flame retardancy of this laminate, test specimen was completely burned down.

Even in the specimen of the laminate reducing the resin composition, it was completely burned down.

TABLE 1

| | | | Exam- | Exam- | Exam- | Exam- | Comp. | Comp. | Comp. | Comp. |
|---|---|---|---|---|---|---|---|---|---|---|
| | | | ple2 | ple3 | ple4 | ple5 | Example4 | Example5 | Example6 | Example7 |
| Used | Varnish | | (I) | (I) | (I) | (I) | (II) | (III) | (IV) | (IV) |
| modified | Composition | (A)Polymaleimide | 45 | 45 | 45 | 45 | 45 | 56.6 | 38.5 | Same Left |
| polyimide | (%) | (B)Epoxy Resin | | | | | | | | |
| resin comp. | | (Epoxy Equiv.) | | | | | | | | |
| Varnish | | NC-3000-H (290) | 36.8 | 36.8 | 36.8 | 36.8 | | | | |
| | | EXA-4710 (173) | | | | | 31.1 | | | |
| | | JER 1032 (170) | | | | | | 21.2 | | |
| | | JER 10001 (475) | | | | | | | 46.2 | 46.2 |
| | | (C)Phenolic resin | | | | | | | | |
| | | (OH Equiv.) | | | | | | | | |
| | | SN-485 (215) | 13.7 | 13.7 | 13.7 | 13.7 | 19.4 | 16.5 | 11.5 | 11.5 |
| | | (D)Glicidyl Ether | | | | | | | | |
| | | Comp. | | | | | | | | |
| | | NeoallylG | 4.5 | 4.5 | 4.5 | 4.5 | 4.5 | 5.7 | 3.8 | 3.8 |

| | | | | | | | | | |
|---|---|---|---|---|---|---|---|---|---|
| | (B)/(C) Equiv. Ratio | 2.0 | 2.0 | 2.0 | 2.0 | 2.0 | 1.9 | 1.8 | 1.8 |
| | (A)/(B + C) Equiv. Ratio | 0.89 | 0.89 | 0.89 | 0.89 | 0.89 | 1.50 | 0.67 | 0.67 |
| Comp. Of | Resin Content (wt %) | 25 | 29 | 30 | 25 | | 45 | 46 | 30 |
| Laminate | Glass Cloth (wt %) | 58 | 71 | 55 | 58 | | 55 | 54 | 70 |
| | Aluminum Hydoxide (wt %) | 17 | | | | | | | |
| | Caicined Talc (wt %) | | | 15 | | | | | |
| | Oxy Aluminum oxide (wt %) | | | | 17 | | | | |
| Evaluation | Glass Transition Point | >300 | >300 | >300 | >300 | Prepreg | >300 | >300 | >300 |
| of | Flame Retardancy | V-0 | V-0 | V-0 | V-0 | cannot be | Burn Down | Burn Down | Burn Down |
| Properties | Cu Peeling Strength | 1.2 | 1.3 | 1.3 | 1.2 | formed | 1.7 | 1.3 | 1.0 |
| | Solder Dip Resistance | ◯ | ◯ | ◯ | ◯ | | ◯ | ◯ | ◯ |
| | Presence or Absence of Halogen | absence | absence | absence | absence | absence | absence | absence | absence |

1. A modified polyimide resin composition which contains
(A) a polymaleimide compound represented by the following general formula[1];
(B) an epoxy resin having at least two glycidyl groups in the molecule represented by the following general formula [2]; and
(C) a phenolic compound having two OH groups in the molecule. 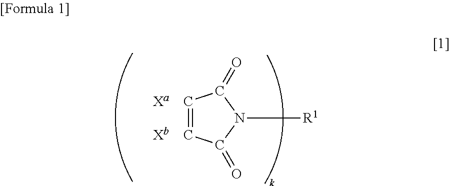
(wherein, R¹ represents k valence organic group, X^{a}, X^{b} may be the same or different, and represents one valence atom or group selected from a hydrogen atom or an organic group, k is an integer of 2 or more.) 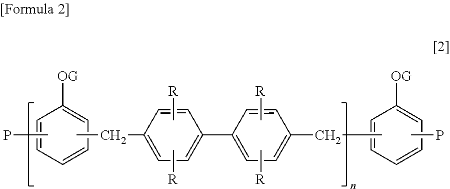
(wherein, n represents an average value and is the value of 1 to 15, G represents a glycidyl group, R may be the same or different, represents alkyl group or alkene group having 1 to 8 carbon numbers, and P represents a hydrogen atom, an alkyl group, an alkene group or an aromatic hydrocarbon group.)

2. The modified polyimide resin obtained by reacting the resin composition according to claim 1 by heat treatment.

3. The modified polyimide resin obtained by reacting between at least (A) and (C) by heat treatment of (A), (B), (C) of resin composition according to claim 1.

4. The resin modified polyimide resin composition according to claim 1, which further contains (D) glycidyl ether compound and (E) at least one compound selected from the compound having at least one active hydrogen.

5. A prepreg obtained by impregnating the modified polyimide resin composition according to claim 1 into the substrate.

6. A composite obtained by heating and pressing the material laminated with one piece or a plurality of pieces of prepreg according to claim 5.

7. A laminate obtained by integrating metallic foil on one surface or both surfaces of the most outer layer of the plate laminated with one piece or a plurality of pieces of prepreg according to claim 5.

8. A prepreg obtained by impregnating the modified polyimide resin composition according to claim 4 into the substrate.

9. A composite obtained by heating and pressing the material laminated with one piece or a plurality of pieces of prepreg according to claim 8.

10. A laminate obtained by integrating metallic foil on one surface or both surfaces of the most outer layer of the plate laminated with one piece or a plurality of pieces of prepreg according to claim 9.
